(19) United States
(12) Patent Application Publication
(10) Pub. No.: US 2008/0204334 A1
(43) Pub. Date: Aug. 28, 2008

(54) Broadcasting receiving apparatus

(75) Inventor: Shusuke Narita, Osaka (JP)

Correspondence Address: MORGAN LEWIS & BOCKIUS LLP, 1111 PENNSYLVANIA AVENUE NW, WASHINGTON, DC, 20004, US

(73) Assignee: Funai Electric Co., Ltd., Osaka (JP)

(21) Appl. No.: 12/068,857

(22) Filed: Feb. 12, 2008

(30) Foreign Application Priority Data
Feb. 13, 2007 (JP) 2007-031567

(51) Int. Cl. G01R 29/08

(52) U.S. Cl. 343/703

(57) ABSTRACT

An MPU (11) of a digital broadcasting receiver has functional units that includes an antenna judging unit (115) for deciding whether an antenna connected to an antenna unit (151) is a bidirectional antenna having directivities in two directions forming substantially 180 degrees with each other or a unidirectional antenna having its directivity only in one direction, a second intensity obtaining unit (116) for setting the connected antenna in a plurality of prescribed directions between 0 degree and 180 degrees or between 0 degree and 360 degrees so that reception intensities are obtained for the individual setting directions if it is decided that the antenna is a bidirectional antenna or a unidirectional antenna, and a direction setting unit (117) for setting a direction of the connected antenna in the direction of the maximum reception intensity among the obtained reception intensities.

This application is based on Japanese Patent Application No. 2007-031567 filed on Feb. 13, 2007, and the content of which are hereby incorporated by reference.

### BACKGROUND OF THE INVENTION

1. Field of the Invention

The present invention relates to a broadcasting receiving apparatus to which a smart antenna that is structured as an antenna changeable in directivity direction is connectable and which can receive television broadcast through the connected antenna and output the television broadcast onto a monitor.

2. Description of Related Art

A directional antenna such as Yagi antenna or the like has been hitherto used to receive television broadcast. Such a directional antenna can receive even weak electric waves because of strong directivity, however, it has a drawback that it can receive only electric waves in a specific direction. Such a characteristic causes little problem in Japan or the like where transmission towers for transmitting television broadcasting waves concentrate in one place. However, United States of America or the like has many areas where a plurality of transmission towers are distributed so as to surround an urban area, thus when a directional antenna is used, there exists a station which cannot be received television broadcasting waves although it is near to a transmission tower.

Therefore, in order to solve such a problem, EIA (Electric Industries Alliance)−909 (=Antenna Control Interface) as a standard to control an antenna from a receiving apparatus has been constituted so that the directivity of the antenna can be changed. This is a standard for connecting a directivity changeable antenna (hereinafter referred to as “smart antenna”) to a receiving apparatus and control the antenna from the receiving apparatus side through a modular terminal.

In a television broadcasting receiving apparatus to which the smart antenna is connectable as described above, it is necessary to set a direction of the smart antenna along which a television broadcast signal can be received under the best state (hereinafter referred to as “optimum reception direction”), and various kinds of apparatus and methods for setting the optimum reception direction have been proposed.

For example, JP-A-2006-201285 discloses a TV broadcasting receiving apparatus that outputs a reception direction control signal for successively instructing all the reception directions to a connected antenna, measures the reception intensity of the television broadcast signal received when each reception direction is instructed and judges on the basis of the measured reception intensity whether the connected antenna is a smart antenna or not. According to the TV broadcasting receiving apparatus as described above, it can be judged whether the connected antenna is a smart antenna or not, and also proper reception control can be performed in accordance with whether the connected antenna is a smart antenna or not.

However, in the above described TV broadcasting receiving apparatus, the directivity of the connected smart antenna cannot be identified, thus there is a problem that much time is required for a process of setting the optimum reception direction. That is, when the connected smart antenna is a bidirectional antenna having directivity in two directions which are intersected to each other at substantially 180 degrees, it is sufficient to obtain the reception intensity to set the optimum reception direction in each direction within a substantially 180 degrees range. However, when it is unclear whether the connected smart antenna is a bidirectional antenna or not, it is required to obtain reception intensity to set the optimum reception direction in each direction within a substantially 360 degrees range.

### SUMMARY OF THE INVENTION

The present invention is made in view of the above described problem and it is an object of the present invention to provide a broadcasting receiving apparatus that is capable of setting the optimal reception direction efficiently.

To attain the above described object a broadcasting receiving apparatus in accordance with the present invention is a broadcasting receiving apparatus to which a smart antenna as an antenna having a changeable directivity direction is connectable and which can receive television broadcast through the connected antenna and output the received television broadcast onto a monitor, the apparatus includes: a first judging unit for deciding whether or not the connected antenna is a smart antenna; a second judging unit for deciding whether the connected antenna is a bidirectional antenna having directivities in two directions forming substantially 180 degrees with each other or a unidirectional antenna having its directivity only in one direction if it is decided that the connected antenna is a smart antenna by the first judging unit; an intensity obtaining unit for setting the connected antenna in a plurality of prescribed directions and for obtaining reception intensities in the individual setting directions only in the case where the first judging unit decides that the connected antenna is a smart antenna; and a direction setting unit for setting a direction of the connected antenna in a direction of a maximum reception intensity among the reception intensities obtained by the intensity obtaining unit, and the apparatus is characterized by that the intensity obtaining unit sets the connected antenna in a plurality of prescribed directions between a prescribed direction and the direction forming 180 degrees with each other so as to obtain reception intensities in the individual setting directions if the second judging unit decides that the connected antenna is a bidirectional antenna, while the intensity obtaining unit sets the connected antenna in a plurality of prescribed directions between a prescribed direction and the direction forming 360 degrees with each other so as to obtain reception intensities in the individual setting directions if the second judging unit decides that the connected antenna is a unidirectional antenna.

According to this structure, it is decided whether or not the connected antenna is a smart antenna. If it is decided that the connected antenna is a smart antenna, it is decided whether the connected antenna is a bidirectional antenna having directivities in two directions forming substantially 180 degrees with each other or a unidirectional antenna having its directivity only in one direction. Then, only in the case where it is decided to be a smart antenna, the connected antenna is set in a plurality of prescribed directions so that reception intensities are obtained for the individual setting directions. In addition, if it is decided that the antenna is a bidirectional antenna, the connected antenna is set in a plurality of prescribed directions between a prescribed direction and the direction forming 180 degrees with each other so that reception intensities are obtained for the individual setting directions. If it is decided that the antenna is a unidirectional antenna, the connected antenna is set in a plurality of prescribed directions between a prescribed direction and the direction forming 360 degrees with each other so as to obtain reception intensities in the individual setting directions. Further, the direction of the connected antenna is set in the direction of the maximum reception intensity among the obtained reception intensities. Therefore, an optimal reception direction can be set efficiently.

More specifically, since reception intensities in appropriate number of directions are obtained in accordance with a type of the antenna (i.e., whether the antenna is a smart antenna or not and whether the antenna is a bidirectional antenna or not), the optimal reception direction can be set efficiently. In other words, if it is decided that the antenna is not a smart antenna, it is not necessary to obtain reception intensities in a plurality of directions, so the optimal reception direction can be set efficiently. Further, if it is decided that the antenna is a bidirectional antenna, the connected antenna is set in a plurality of prescribed directions between a prescribed direction and the direction forming 180 degrees with each other so that reception intensities are obtained for the individual setting directions. Then, the direction of the connected antenna is set in a direction of the maximum reception intensity among the obtained reception intensities. Therefore, compared with the case where the antenna is a unidirectional antenna, the time necessary for obtaining reception intensities can be reduced approximately by half.

In addition, as to the broadcasting receiving apparatus according to the present invention having the structure described above, the intensity obtaining unit sets the connected antenna in eight directions forming 22.5 degrees between neighboring directions between a prescribed direction and the direction forming 180 degrees with each other if the second judging unit decides that the connected antenna is a bidirectional antenna, while the intensity obtaining unit sets the connected antenna in sixteen directions forming 22.5 degrees between neighboring directions between a prescribed direction and the direction forming 360 degrees with each other if the second judging unit decides that the connected antenna is a unidirectional antenna.

According to this structure, if it is decided that the antenna is a bidirectional antenna, the connected antenna is set in eight directions forming 22.5 degrees between neighboring directions between a prescribed direction and the direction forming 180 degrees with each other. If it is decided that the antenna is a unidirectional antenna, the connected antenna is set in sixteen directions forming 22.5 degrees between neighboring directions between a prescribed direction and the direction forming 360 degrees with each other. Therefore, the optimal reception direction can be set more efficiently.

More specifically, since the connected antenna is set in eight directions (or sixteen directions) forming a constant angle (here, 22.5 degrees) between neighboring directions, reception intensities in directions corresponding to a spreading angle of directivity of the antenna can be obtained. Therefore, the optimal reception direction can be set more efficiently.

### BRIEF DESCRIPTION OF THE DRAWINGS

FIG. 1 is a block diagram to show an example of the structure of a digital broadcasting receiving apparatus in accordance with the present invention;

FIG. 2 is a block diagram to show an example of the structure of a main part of the digital broadcasting receiving apparatus in accordance with the present invention;

FIGS. 3A to 3C are tables to show an example of information stored in each of a channel storage unit, a judgment value storage unit and a setting direction storage unit;

FIGS. 4A to 4C are diagrams to show the setting direction of a smart antenna, and the directivities of a bidirectional antenna and a unidirectional antenna;

FIG. 5 is a flowchart to show an example of the operation of the digital broadcasting receiving apparatus (mainly MPU);

FIG. 6 is a detailed flowchart (first half part) to show an example of type identifying process executed in step S105 of the flowchart shown in FIG. 5;

FIG. 7 is a detailed flowchart (last half part) to show an example of the type identifying process executed in step S105 of the flowchart shown in FIG. 5;

FIG. 8 is a detailed flowchart to show an example of direction setting process A executed in step S111 of the flowchart shown in FIG. 5;

FIG. 9 is a detailed flowchart (first half part) to show an example of judgment value renewal process executed in step S319 of the flowchart shown in FIG. 8;

FIG. 10 is a detailed flowchart (last half part) to show an example of the judgment value renewal process executed in step S319 of the flowchart shown in FIG. 8;

FIG. 11 is a detailed flowchart to show an example of reception possibility judging process executed in step S115 of the flowchart shown FIG. 5;

FIG. 12 is a detailed flowchart to show an example of direction setting process B executed in step S119 of the flowchart shown in FIG. 5; and

FIG. 13 is a detailed flowchart to show an example of direction setting process C executed in step S121 of the flowchart shown in FIG. 5.

### DETAILED DESCRIPTION OF THE PREFERRED EMBODIMENTS

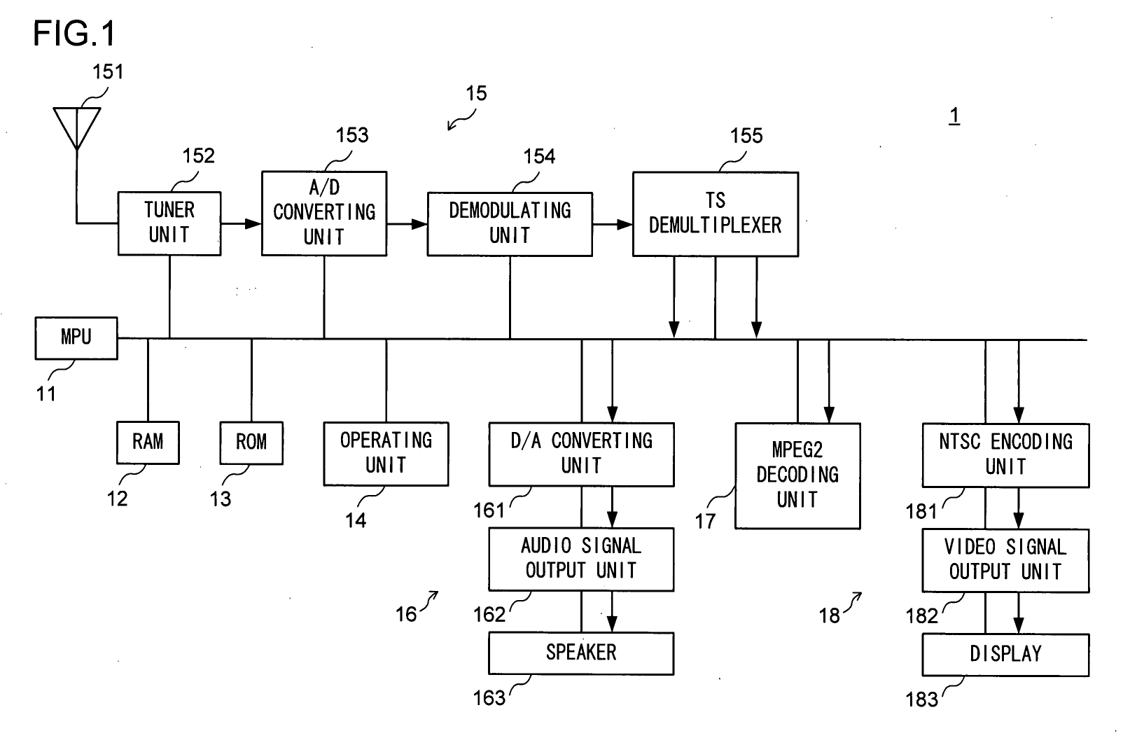

Hereinafter, an embodiment of the present invention will be described with reference to the attached drawings. FIG. 1 is a block diagram to show an example of the structure of a digital broadcasting receiving apparatus in accordance with the present invention. A digital broadcasting receiver 1 (corresponding to the broadcasting receiving apparatus) receives a television broadcast signal and delivers its content to a speaker 163 and a display 183 that will be described later. The digital broadcasting receiver 1 includes a micro processing unit (MPU) 11, random access memory (RAM) 12, read only memory (ROM) 13, an operating unit 14, a receiving unit 15, an sound output unit 16, an MPEG2 decoding unit 17, and an image output unit 18.

The MPU 11 controls the entire operation of the digital broadcasting receiver 1. The RAM 12 is a memory for storing information such as audio information, picture information and the like in a readable and rewritable manner. The ROM 13 is a memory for storing a control program and the like for operating the MPU 11.

The operating unit 14 receives an operation for turning on and off of the power, selecting a channel or other various operations. The receiving unit 15 (corresponding to a part of an intensity obtaining unit) receives a television broadcast signal and demodulates the same. It includes an antenna unit 151, a tuner unit 152, an A/D converter unit 153, a demodulator unit 154, and a TS demultiplexer 155.

The antenna unit 151 has a structure to be connected to a smart antenna that can change its directivity in accordance with the EIA-909 standard for receiving a television broadcasting wave. The tuner unit 152 selects a broadcast signal of a preset channel from the television broadcasting waves received by the antenna unit 151. The A/D converter unit 153 converts an output signal (i.e., an analog signal) of the tuner unit 152 into digital information. The demodulator unit 154 demodulates the output information of the A/D converter unit 153. The TS (Transport Stream) demultiplexer 155 demultiplexes the output information demodulated by the demodulator unit 154 into individual types of information (i.e., picture information, audio information, control information and the like), which are delivered.

The sound output unit 16 delivers sounds corresponding to a television broadcast signal received by the receiving unit 15. It includes a D/A converting unit 161, an audio signal output unit 162 and a speaker 163. The D/A converting unit 161 converts the audio information (i.e., the digital information) delivered from the TS demultiplexer 155 into an analog signal. The audio signal output unit 162 delivers the audio signal that is the analog signal converted by the D/A converting unit 161. The speaker 163 produces a sound corresponding to the audio signal delivered from the audio signal output unit 162.

The MPEG (Motion Picture Experts Group) 2 decoding unit 17 decodes the picture information delivered from the TS demultiplexer 155 into picture information before compression.

The image output unit 18 delivers the picture information decoded by the MPEG2 decoding unit 17. It includes an NTSC encoding unit 181, a video signal output unit 182 and the display 183. The NTSC (National Television Standards Committee) encoder unit 181 converts the picture information decoded by the MPEG2 decoding unit 17 into an NTSC television signal. The video signal output unit 182 delivers the NTSC television signal from the NTSC encoding unit 181 to the display 183. The display 183 (corresponding to the monitor) includes an LCD (Liquid Crystal Display), a PDP (Plasma Display Panel) or the like for displaying a picture corresponding to the television signal delivered from the video signal output unit 182.

Next, an operation of the digital broadcasting receiver 1 receiving a broadcast signal will be described. First, a transmitted digital broadcasting wave is received by the antenna unit 151. If a channel selecting operation is accepted via the operating unit 14, the tuner unit 152 switches a transponder for receiving. The received digital broadcasting wave is converted by the A/D converter unit 153 into digital information, which is demodulated by the demodulator unit 154.

Note that the digital broadcasting wave is transmitted as a TS (Transport Stream) packet from a transmitting side (a transmitting station). This TS packet includes picture information, audio information, control information and the like, which are demultiplexed and delivered by the TS demultiplexer 155 and are stored in the RAM 12. Then, the audio information read from the RAM 12 is converted into the analog signal by the D/A converting unit 161, so that a sound is produced from the speaker 163 via the audio signal output unit 162.

In addition, the picture information read from the RAM 12 is decoded by the MPEG2 decoding unit 17 into picture information before compression, which is converted by the NTSC encoding unit 181 into an NTSC television signal, so that a picture is displayed on the display 183 via the video signal output unit 182.

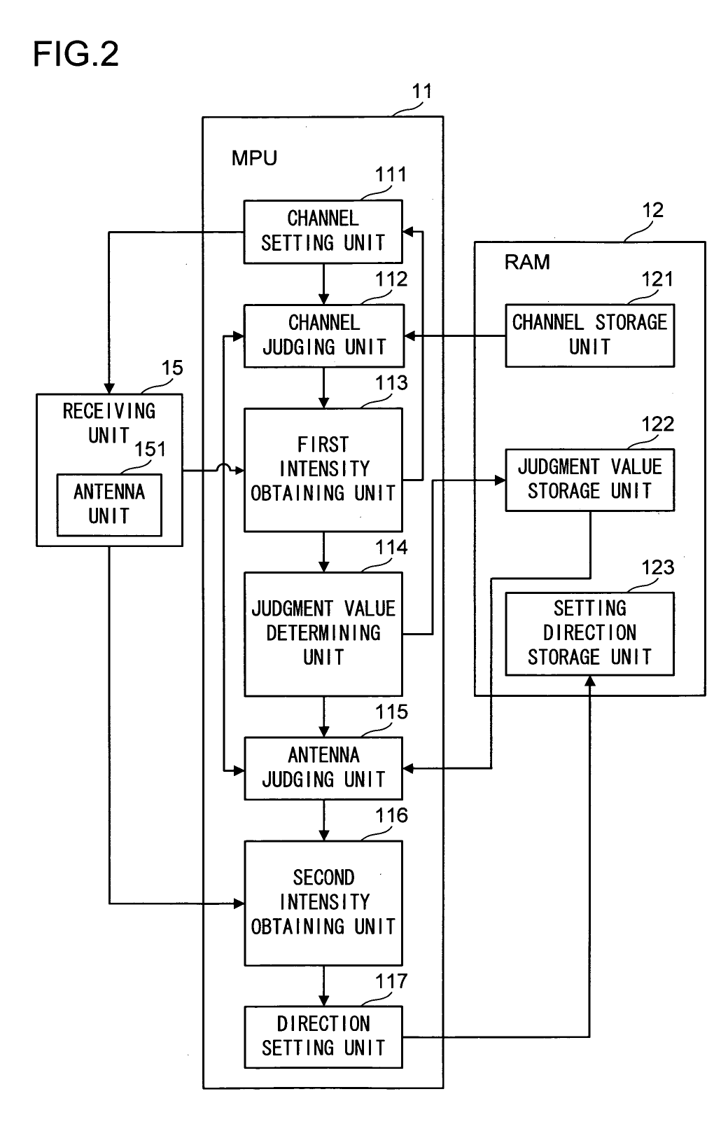

FIG. 2 is a block diagram to show an example of the structure of a main part of the digital broadcasting receiving apparatus 1 in accordance with the present invention. The MPU 11 of the digital broadcasting receiver 1 shown in FIG. 1 includes functional units that are a channel setting unit 111, a channel judging unit 112, a first intensity obtaining unit 113, a judgment value determining unit 114, an antenna judging unit 115, a second intensity obtaining unit 116 and a direction setting unit 117. The RAM 12 includes functional units that are a channel storage unit 121, a judgment value storage unit 122 and a setting direction storage unit 123.

Here, the MPU 11 reads the control program stored in advance in the ROM 13 or the like shown in FIG. 1 and executes the control program, so as to work as the functional units such as the channel setting unit 111, the channel judging unit 112, the first intensity obtaining unit 113, the judgment value determining unit 114, the antenna judging unit 115, the second intensity obtaining unit 116, the direction setting unit 117 and the like. It also lets the RAM 12 work as the functional units such as the channel storage unit 121, the judgment value storage unit 122, the setting direction storage unit 123 and the like.

In addition, among the various data stored in the RAM 12 and the ROM 13 shown in FIG. 1, data that can be stored in a removable recording medium may be read by a driver for a hard disk drive, an optical disc drive, a flexible disc drive, a silicon disc drive, a cassette media reader or the like, for example. In this case, the recording medium is a hard disk, an optical disc, a flexible disc, a CD (Compact Disc), a DVD (Digital Versatile Disc), a semiconductor memory or the like, for example.

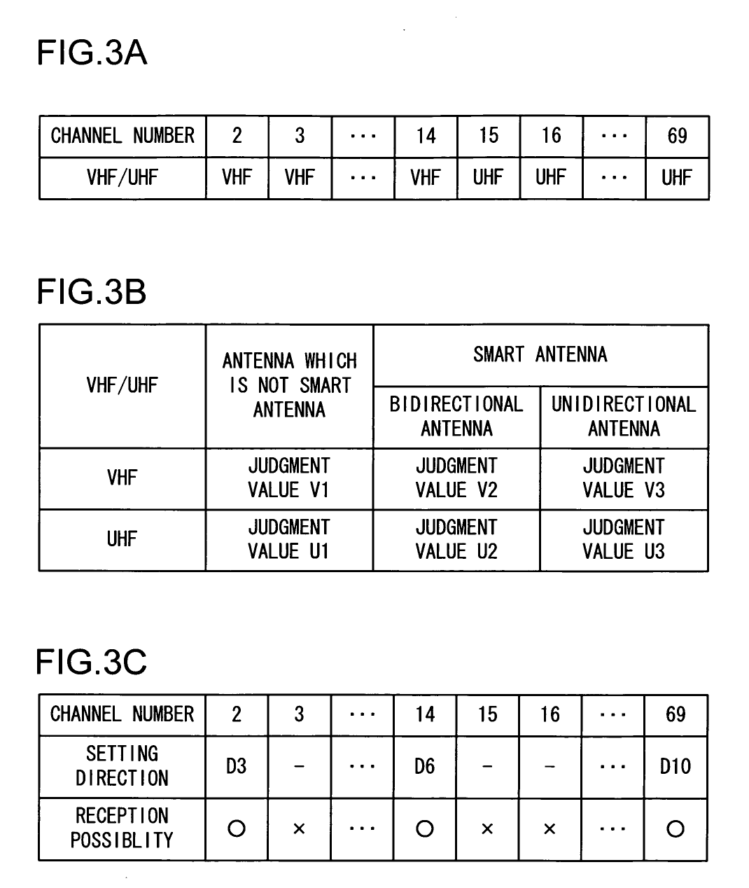

The channel storage unit 121 is a functional unit for storing information of each of preset channels about whether the channel belongs to the UHF (Ultra High Frequency) band or to the VHF (Very High Frequency) band (hereinafter referred to as frequency discrimination information) (see FIG. 3A).

The judgment value storage unit 122 (corresponding to a part of the first judging unit and a part of the second judging unit) is a functional unit for storing judgment values V1-V3 and U1-U3 that are determined by the judgment value determining unit 114 and are used by the antenna judging unit 115 for deciding a type of the antenna (i.e., whether it is a smart antenna or not and whether it is a bidirectional antenna or not) (see FIG. 3B).

The setting direction storage unit 123 is a functional unit for storing information sets of each of preset channels, which include reception possibility information indicating reception possibility decided by the direction setting unit 117 and information indicating a set optimal reception direction (i.e., a direction of the smart antenna for receiving the television broadcast signal in an optimal condition) (see FIG. 3C).

FIGS. 3A to 3C are tables to show examples of information sets stored respectively in the channel storage unit 121, in the judgment value storage unit 122 and in the setting direction storage unit 123. FIGS. 3A to 3C are tables to show an example of information stored in each of a channel storage unit, a judgment value storage unit a setting direction storage unit. Here, it stores information of each channel number about whether the channel belongs to the UHF band or to the VHF band (i.e., the frequency discrimination information). For example, channels of channel numbers “2” to “14” belong to the VHF band while channels of channel numbers “15” to “69” belong to the UHF band.

FIG. 3B is a table to show an example of information stored in the judgment value storage unit 122. Here, the judgment value V1 indicates that the antenna connected to the antenna unit 151 is not a smart antenna in a channel belonging to the VHF band, and the judgment value V2 indicates that the antenna connected to the antenna unit 151 is a smart antenna with two directivities in a channel belonging to the VHF band, and the judgment value V3 indicates that the antenna connected to the antenna unit 151 is a smart antenna with one directivity in a channel belonging to the VHF band.

In addition, the judgment value U1 indicates that the antenna connected to the antenna unit 151 is not a smart antenna as for a channel belonging to the VHF band, and the judgment value U2 indicates that the antenna connected to the antenna unit 151 is a smart antenna with two directivities as for a channel belonging to the VHF band, and the judgment value U3 indicates that the antenna connected to the antenna unit 151 is a smart antenna with one directivity as for a channel belonging to the VHF band.

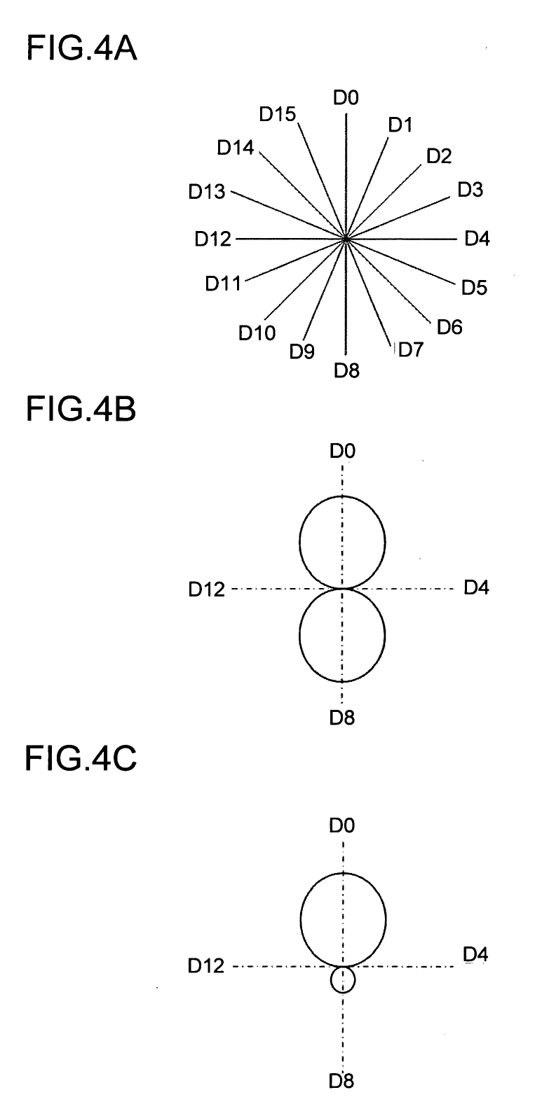

FIG. 3C is a table to show an example of information stored in the setting direction storage unit 123. Here, it stores information of each channel number, which includes information indicating the optimal reception direction set by the direction setting unit 117 and information indicating the reception possibility. For example, a channel of channel number “2” can be received, and the optimal reception direction is the direction D3 (see FIG. 4A). In addition, a channel of channel number “3” cannot be received, for example.

With reference to FIG. 2 again, a functional structure of the MPU 11 will be described. The channel setting unit 111 is a functional unit for setting a channel to be received via the connected antenna in accordance with an instruction from the first intensity obtaining unit 113 and the second intensity obtaining unit 116 via the receiving unit 15 (or the tuner unit 152) among a plurality of preset channels.

The channel judging unit 112 is a functional unit for deciding whether the channel set by the channel setting unit 111 is a channel belonging to the UHF band or a channel belonging to the VHF band. More specifically, the channel judging unit 112 reads out the frequency discrimination information corresponding to the channel number of a channel set by the channel setting unit 111 (i.e., information indicating whether the channel belongs to the UHF band or to the VHF band) from the channel storage unit 121, so as to decide whether the channel belongs to the UHF band or to the VHF band.

The first intensity obtaining unit 113 is a functional unit for letting the channel setting unit 111 set a plurality of channels one by one until the antenna judging unit 115 decides a type of the antenna (i.e., whether the antenna is a smart antenna or not and whether the antenna is a bidirectional antenna or not) and for setting the antenna connected to the antenna unit 151 in a plurality of prescribed directions for individual channels, so as to obtain the reception intensity of each setting direction via the receiving unit 15. Here, a bit error rate (BER) is used as the reception intensity. More specifically, a larger value of the BER indicates a lower value of the reception intensity.

FIGS. 4A to 4C are diagrams to show respectively setting directions of a smart antenna, a directivity of a bidirectional antenna and a directivity of a unidirectional antenna. FIG. 4A is a diagram to show directions of the antenna set by the first intensity obtaining unit 113 and the second intensity obtaining unit 116. As shown in FIG. 4A, the antenna connected to the antenna unit 151 is set in one of sixteen directions D0-D15 that forms 22.5 degrees between neighboring directions.

FIG. 4B is a diagram to show directivities of the bidirectional antenna. The bidirectional antenna has its directivities in two directions (here, direction D0 and direction D8) forming substantially 180 degrees with each other. FIG. 4C is a diagram to show a directivity of the unidirectional antenna. The unidirectional antenna has its directivity only in one direction (here, direction D0).

With reference to FIG. 2 again, the functional structure of the MPU 11 will be described. The judgment value determining unit 114 (corresponding to a part of the first judging unit and a part of the second judging unit) is a functional unit that decides whether the antenna connected to the antenna unit 151 is a smart antenna or not based on the reception intensities of individual directions obtained by the first intensity obtaining unit 113 and determines the judgment values V1-V3 and U1-U3 (see FIG. 3B) for deciding whether the antenna connected to the antenna unit 151 is a bidirectional antenna or a unidirectional antenna, so as to store the determined judgment values V1-V3 and U1-U3 in the judgment value storage unit 122.

In addition, the judgment value determining unit 114 determines the judgment values V1-V3 and U1-U3 separating the channels decided by the channel judging unit 112 to belong to the UHF band from channels belonging to the VHF band. In addition, the judgment value determining unit 114 determines a maximum reception intensity (here, a minimum BER), a reception intensity in the direction forming 90 degrees with the direction in which the maximum reception intensity is obtained, a reception intensity in the direction forming 180 degrees with the direction in which the maximum reception intensity is obtained, and the judgment values V1-V3 and U1-U3.

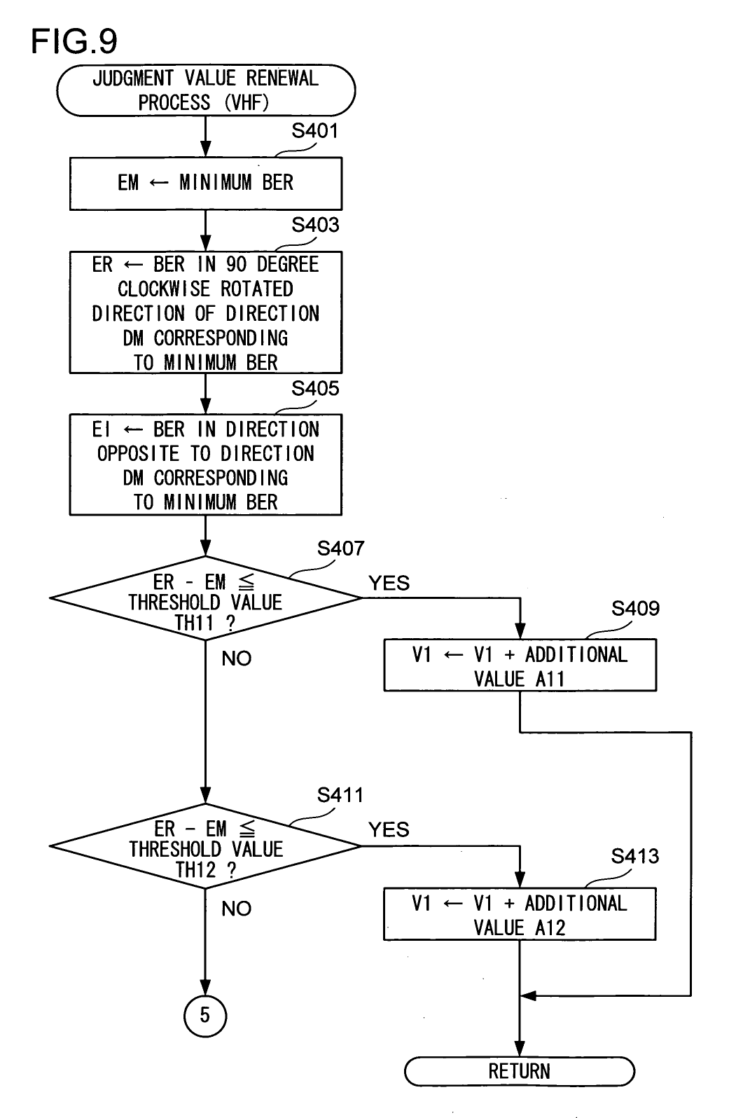

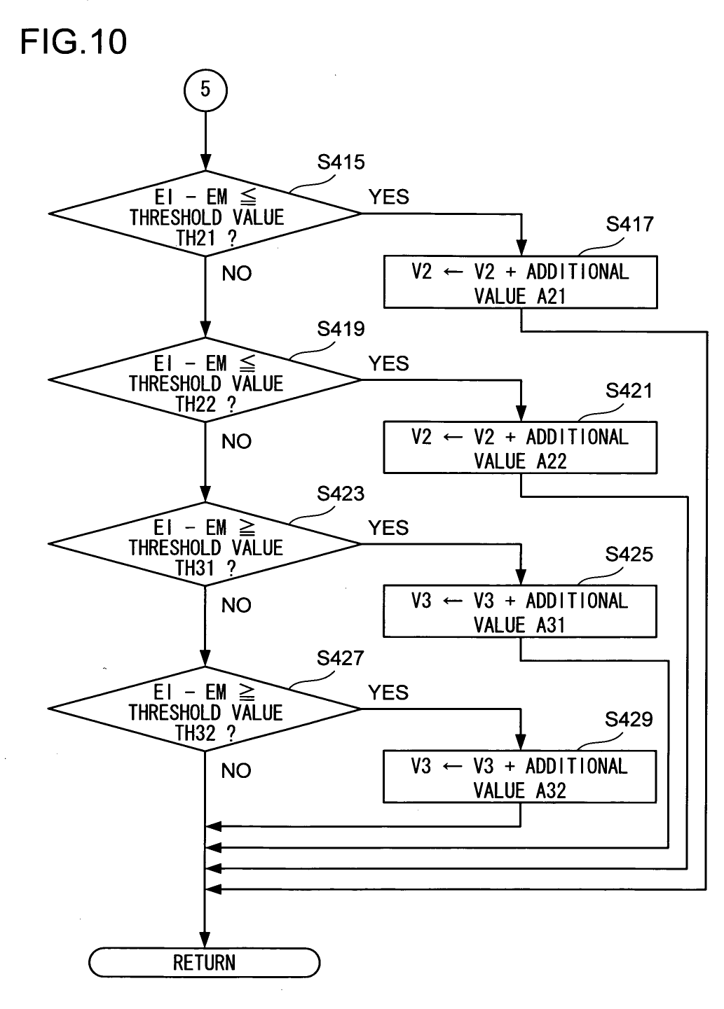

More specifically, the judgment value determining unit 114 determines the judgment values V1-V3 and U1-U3 by the following method (see flowcharts shown in FIGS. 9 and 10). Here, for convenience sake, the case where the channel set by the channel setting unit 111 is a channel belonging to the VHF band will be described. First, “0” is set as an initial value of the judgment values V1-V3. Then, a minimum BER value is set as a parameter EM, and a BER value in the rightward direction by 90 degrees from the direction corresponding to the minimum BER is set as a parameter ER, and a BER value in the direction opposite to the direction corresponding to the minimum BER is set as a parameter E1. Next, if a difference between the parameter ER and the parameter EM is smaller than or equal to a preset predetermined threshold value TH11 or TH12, a preset positive additional value A11 or A12 is added to the judgment value V1.

Then, if a difference between the parameter E1 and the parameter EM is smaller than or equal to a preset predetermined threshold value TH21 or TH22, a preset positive additional value A21 or A22 is added to the judgment value V2. Further, if a difference between the parameter E1 and the parameter EM is larger than or equal to a preset predetermined threshold value TH31 or TH32, a preset positive additional value A31 or A32 is added to the judgment value V3.

More specifically, the judgment value determining unit 114 adds the judgment value V1 indicating that the antenna is not a smart antenna if a difference between the minimum BER value and the BER value in the rightward direction by 90 degrees from the direction corresponding to the minimum BER is small. In addition, the judgment value determining unit 114 adds the judgment value V2 indicating that the antenna is a bidirectional antenna if a difference between the minimum BER value and the BER value in the direction opposite to the direction corresponding to the minimum BER is large. Further, the judgment value determining unit 114 adds the judgment value V3 indicating that the antenna is a unidirectional antenna if a difference between the minimum BER value and the BER value in the direction opposite to the direction corresponding to the minimum BER is large.

The antenna judging unit 115 (corresponding to a part of the first judging unit and a part of the second judging unit) is a functional unit that decides whether the antenna connected to the antenna unit 151 is a smart antenna or not based on the judgment values V1-V3 and U1-U3 stored in the judgment value storage unit 122 and decides whether the antenna connected to the antenna unit 151 is a bidirectional antenna or a unidirectional antenna.

In addition, the antenna judging unit 115 decides whether the antenna is a smart antenna or not and whether the antenna is a bidirectional antenna or a unidirectional antenna discriminating channels decided by the channel judging unit 112 to belong to the UHF band from channels belonging to the VHF band.

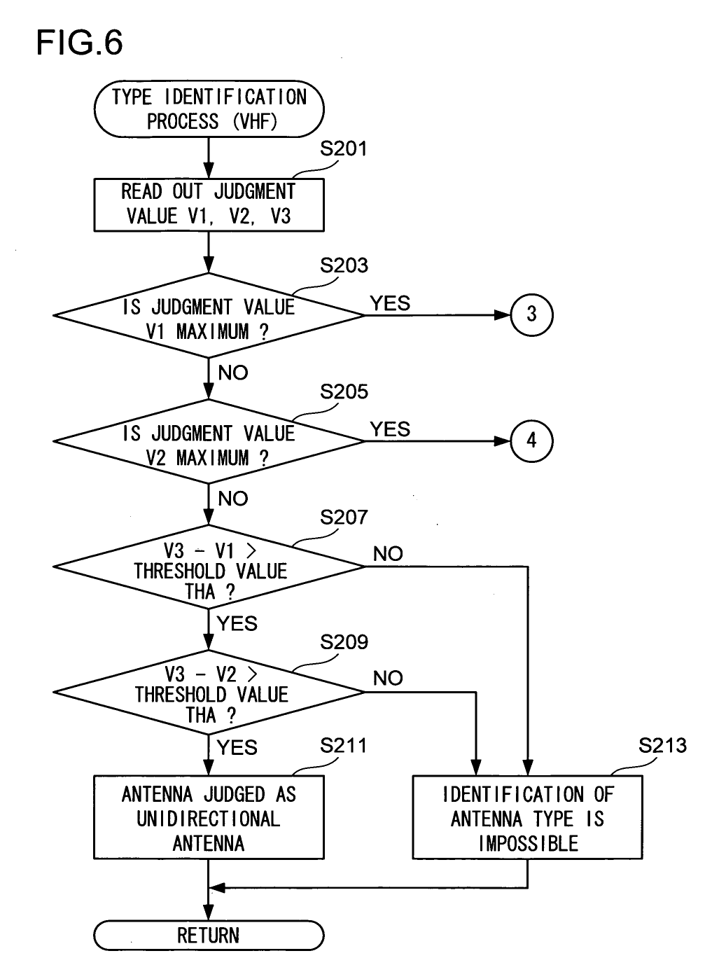

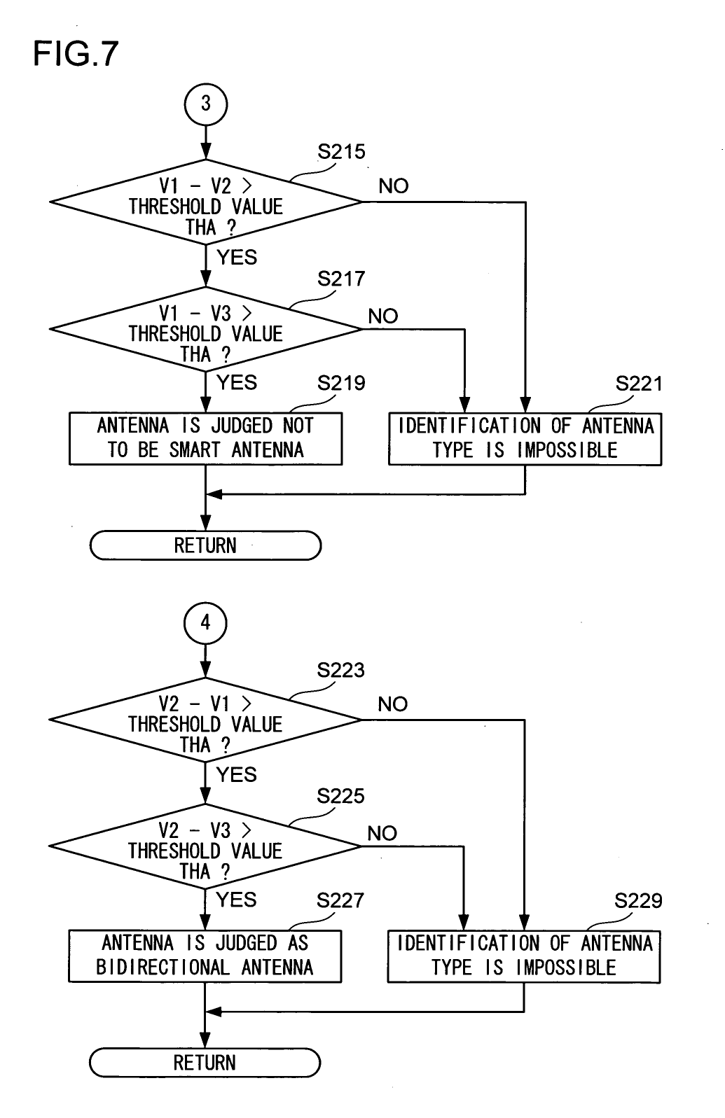

More specifically, the antenna judging unit 115 decides that the antenna is not a smart antenna if differences obtained by subtracting the judgment values V2 and V3 from the judgment value V1 are both larger than a preset predetermined threshold value THA, and it decides that the antenna is a smart antenna and a bidirectional antenna if differences obtained by subtracting the judgment values V1 and V3 from the judgment value V2 are both larger than the preset predetermined threshold value THA, and it decides that the antenna is a smart antenna and a unidirectional antenna if differences obtained by subtracting the judgment values V1 and V2 from the judgment value V3 are both larger than the preset predetermined threshold value THA (see the flowcharts shown in FIGS. 6 and 7).

The second intensity obtaining unit 116 (corresponding to a part of the intensity obtaining unit) is a functional unit that lets the channel setting unit 111 set one of channels and sets the antenna connected to the antenna unit 151 in a plurality of prescribed directions only in the case where the antenna judging unit 115 decides that the antenna connected to the antenna unit 151 is a smart antenna, so as to obtain reception intensities in the individual setting directions. More specifically, the second intensity obtaining unit 116 obtains the reception intensity only one time if the antenna judging unit 115 has decided that the antenna connected to the antenna unit 151 is not a smart antenna.

In addition, if the antenna judging unit 115 has decided that the antenna is a bidirectional antenna, the second intensity obtaining unit 116 sets the connected antenna in eight directions (i.e., directions D0-D7) forming 22.5 degrees between neighboring directions between a prescribed direction and the direction forming 180 degrees with each other so as to obtain the reception intensities of the individual setting directions. Further, if the antenna judging unit 115 has decided that the antenna is a unidirectional antenna, the second intensity obtaining unit 116 sets the connected antenna in sixteen directions (i.e., directions D0-D15) forming 22.5 degrees between neighboring directions between a prescribed direction and the direction forming 360 degrees with each other so as to obtain the reception intensities of the individual setting directions.

The direction setting unit 117 is a functional unit for setting the optimal reception direction of the antenna connected to the antenna unit 151 in the direction of the maximum reception intensity among the reception intensities obtained by the first intensity obtaining unit 113 and the second intensity obtaining unit 116 so as to store the setting direction in the setting direction storage unit 123. However, if the maximum reception intensity is lower than or equal to a preset predetermined threshold value, the direction setting unit 117 stores information indicating that reception cannot be performed in the setting direction storage unit 123.

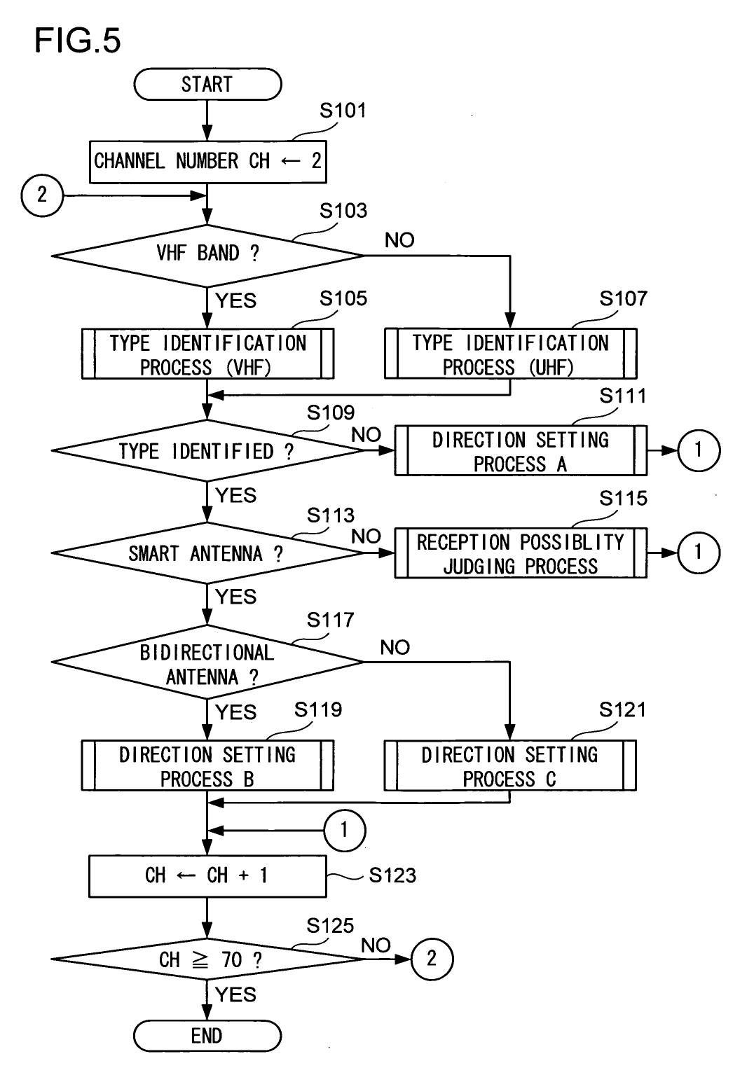

FIG. 5 is a flowchart to show an example of an operation of the digital broadcasting receiver 1 (mainly the MPU 11). First, the channel setting unit 111 sets the channel number CH to “2” (S101). Then, the channel judging unit 112 decides whether or not the channel corresponding to the channel number CH set in the step S101 is a channel belonging to the VHF band (S103).

If it is decided to be a channel belonging to the VHF band (YES in S103), the antenna judging unit 115 performs a type identification process (VHF) for deciding a type of the antenna connected to the antenna unit 151 (i.e., whether the antenna is a smart antenna or not and whether the antenna is a bidirectional antenna or not) (S105). If it is decided not to be a channel belonging to the VHF band (i.e., to be a channel belonging to the UHF band) (NO in S103), the antenna judging unit 115 performs a type identification process (UHF) for deciding a type of the antenna connected to the antenna unit 151 (i.e., whether the antenna is a smart antenna or not and whether the antenna is a bidirectional antenna or not) (S107).

When the process in the step S105 or the step S107 is finished, the first intensity obtaining unit 113 decides whether the decision of a type of the antenna connected to the antenna unit 151 is completed or not (S109). If it is decided that the decision of a type of the antenna is not completed (NO in S109), the first intensity obtaining unit 113 and the judgment value determining unit 114 update the judgment value and perform a direction setting process A for setting the optimal reception direction (S111), and the process goes to step S123.

If it is decided that the decision of a type of the antenna is completed (YES in S109), the second intensity obtaining unit 116 decides whether or not it is decided that the antenna is a smart antenna in the step S105 or the step S107 (S113). If it is decided not to be a smart antenna (NO in S113), the second intensity obtaining unit 116 and the direction setting unit 117 perform a reception possibility judging process for deciding a reception possibility (S115), and the process goes to the step S123.

If it is decided that the antenna is a smart antenna (YES in S113), the second intensity obtaining unit 116 decides whether or not it is decided that the antenna is a bidirectional antenna in the step S105 or the step S107 (S117). If it is decided that the antenna is a bidirectional antenna (NO in S117), the second intensity obtaining unit 116 and the direction setting unit 117 perform a direction setting process B for setting the optimal reception direction of the bidirectional antenna (S119), and the process goes to the step S123. If it is decided that the antenna is not a bidirectional antenna (i.e., is a unidirectional antenna) (NO in S117), the second intensity obtaining unit 116 and the direction setting unit 117 perform a direction setting process C for setting the optimal reception direction of the unidirectional antenna (S121), and the process goes to the step S123.

If the process in the step S111, the step S115, the step S119 or the step S121 is finished, the channel setting unit 111 increments the channel number CH by one (S123), and it is decided whether the channel number CH is larger than or equal to “70” (S125). If it is decided that the channel number CH is not larger than or equal to “70” (i.e., smaller than or equal to “69”) (NO in S125), the process goes back to the step S103, and the process in the step S103 and in the subsequent steps is performed repeatedly. If it is decided that the channel number CH is larger than or equal to “70” (YES in S125), the process is finished.

FIGS. 6 and 7 show a detail flowchart of an example of the type discrimination process performed in the step S105 of the flowchart shown in FIG. 5. Here, for convenience sake, the type discrimination process (VHF) performed in the step S105 will be described. A flowchart of the type discrimination process (UHF) performed in the step S107 is obtained by replacing the judgment values V1-V3 in the flowchart of the type discrimination process (VHF) with judgment values U1-U3, respectively. Note that all the following processes are performed by the antenna judging unit 115.

First, the judgment values V1-V3 are read out from the judgment value storage unit 122 (S201). Then, it is decided whether the judgment value V1 is the largest value or not among the judgment values V1-V3 (S203). If it is decided that the judgment value V1 is the largest value (YES in S203), the process goes to step S215 shown in FIG. 7. If it is decided that the judgment value V1 is not the largest value (NO in S203), it is decided whether the judgment value V2 is the largest value or not among the judgment values V1-V3 (S205). If it is decided that the judgment value V2 is the largest value (YES in S205), the process goes to step S223 shown in FIG. 7.

If it is decided that the judgment value V2 is not the largest value (NO in S205), it is decided whether or not a difference obtained by subtracting the judgment value V1 from the judgment value V3 is larger than a preset threshold value THA (S207). If it is decided to be smaller than or equal to the threshold value THA (NO in S207), it is decided that a type of the antenna cannot be decided (S213), and the process is returned. If it is decided to be larger than the threshold value THA (YES in S207), it is decided whether or not a difference obtained by subtracting the judgment value V2 from the judgment value V3 is larger than the preset threshold value THA (S209). If it is decided to be smaller than or equal to the threshold value THA (NO in S209), it is decided that a type of the antenna cannot be decided (S213), and the process is returned. If it is decided to be larger than the threshold value THA (YES in S209), it is decided that the antenna is a smart antenna and a unidirectional antenna (S211), and the process is returned.

In case of “YES” in the step S203, it is decided whether or not a difference obtained by subtracting the judgment value V2 from the judgment value V1 is larger than the preset threshold value THA as shown in FIG. 7 (S215). If it is decided to be smaller than or equal to the threshold value THA (NO in S215), it is decided that a type of the antenna cannot be decided (S221), and the process is returned. If it is decided to be larger than the threshold value THA (YES in S215), it is decided whether or not a difference obtained by subtracting the judgment value V3 from the judgment value V1 is larger than the preset threshold value THA (S217). If it is decided to be smaller than or equal to the threshold value THA (NO in S217), it is decided that a type of the antenna cannot be decided (S221), and the process is returned. If it is decided to be larger than the threshold value THA (YES in S217), it is decided that the antenna is not a smart antenna (S219), and the process is returned.

In case of “YES” in the step S205, it is decided whether or not a difference obtained by subtracting the judgment value V1 from the judgment value V2 is larger than the preset threshold value THA as shown in FIG. 7 (S223). If it is decided to be smaller than or equal to the threshold value THA (NO in S223), it is decided that a type of the antenna cannot be decided (S229), and the process is returned. If it is decided to be larger than the threshold value THA (YES in S223), it is decided whether or not a difference obtained by subtracting the judgment value V3 from the judgment value V2 is larger than the preset threshold value THA (S225). If it is decided to be smaller than or equal to the threshold value THA (NO in S225), it is decided that a type of the antenna cannot be decided (S229), and the process is returned. If it is decided to be larger than the threshold value THA (YES in S225), it is decided that the antenna is a smart antenna and a bidirectional antenna (S227), and the process is returned.

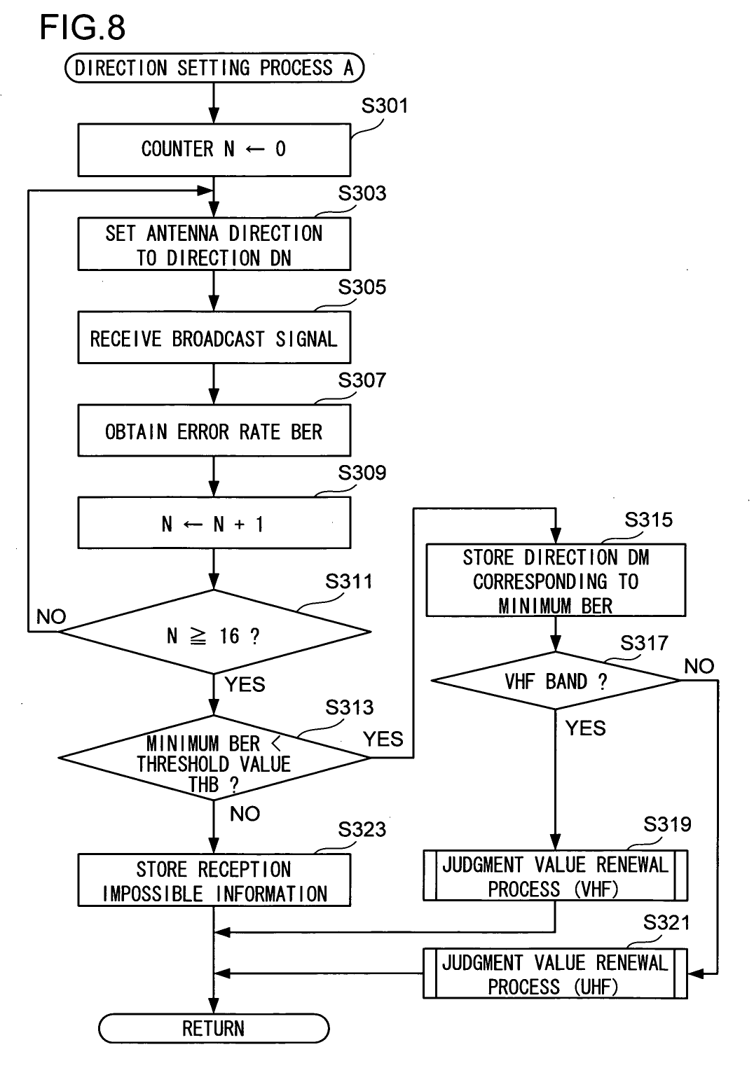

FIG. 8 is a detail flowchart to show an example of the direction setting process A performed in the step S111 of the flowchart shown in FIG. 5. First, the first intensity obtaining unit 113 sets a counter N for counting directions of the antenna to an initial value “0” (S301). Then, the first intensity obtaining unit 113 sets the direction of the antenna connected to the antenna unit 151 to a direction DN (here, N is one of vales 0-15, that is a value of the counter N) (S303). Next, the first intensity obtaining unit 113 receives a broadcast signal via the receiving unit 15 (S305). Next, the first intensity obtaining unit 113 obtains the bit error rate BER (S307). Then, the first intensity obtaining unit 113 increments a value of the counter N by one (S309), and it is decided whether or not the value of the counter N is larger than or equal to 16 (S311). If it is decided not to be larger than or equal to 16 (i.e., to be smaller than or equal to 15) (NO in S311), the process goes back to the step S303, and the process in the step S303 and in the subsequent steps is performed repeatedly.

If it is decided to be larger than or equal to 16 (YES in S311), the direction setting unit 117 decides whether or not the minimum bit error rate BER among sixteen bit error rates BER obtained in the step S307 is smaller than a preset predetermined threshold value THB (S313). If it is decided to be larger than or equal to the threshold value THB (NO in S313), the direction setting unit 117 decides that reception cannot be performed. Then, information indicating that reception cannot be performed is stored in the setting direction storage unit 123 (S323), and the process is returned. If it is decided to be smaller than or equal to the threshold value THB (YES in S313), the direction setting unit 117 stores information indicating that reception can be performed and the direction DM corresponding to the minimum bit error rate BER (a value of M that is one of values 0-15) in the setting direction storage unit 123 (S315).

Then, the channel judging unit 112 decides whether or not the channel of the channel number CH set in the step S101 or the step S123 shown in FIG. 5 is a channel belonging to the VHF band (S317). If it is decided to be a channel belonging to the VHF band (YES in S317), the judgment value determining unit 114 performs a judgment value update process (VHF) for updating the judgment values V1-V3 stored in the judgment value storage unit 122 (S319), and the process is returned. If it is decided not to be a channel belonging to the VHF band (i.e., to be a channel belonging to the UHF band) (NO in S317), the judgment value determining unit 114 performs a judgment value update process (UHF) for updating the judgment values U1-U3 stored in the judgment value storage unit 122 (S321), and the process is returned.

FIGS. 9 and 10 show a detail flowchart of an example of the judgment value update process performed in the step S319 of the flowchart shown in FIG. 8. Here, for convenience sake, the judgment value update process (VHF) performed in the step S319 will be described. A flowchart of the judgment value update process (UHF) performed in the step S321 is obtained by replacing the judgment values V1-V3 in the flowchart of the judgment value update process (VHF) with the judgment values U1-U3, respectively. Note that the following processes are all performed by the judgment value determining unit 114.

First, the minimum bit error rate BER value is set to the parameter EM (S401). Then, the bit error rate BER value in the rightward direction by 90 degrees from the direction DM corresponding to the minimum bit error rate BER is set to the parameter ER (S403). Next, the bit error rate BER value in the direction opposite to the direction DM corresponding to the minimum bit error rate BER is set to the parameter E1 (S405). Next, it is decided whether a difference obtained by subtracting the parameter ER from the parameter E1 is smaller than or equal to a preset positive threshold value TH11 (S407). If it is decided to be smaller than or equal to the threshold value TH11 (YES in S407), a preset positive additional value A11 (e.g., “2”) is added to the judgment value V1 (S409), and the process is returned.

If it is decided not to be smaller than or equal to the threshold value TH11 (NO in S407), it is decided whether or not a difference obtained by subtracting the parameter ER from the parameter E1 is smaller than or equal to a positive threshold value TH12 that is larger than the preset threshold value TH11 (S411). If it is decided to be smaller than or equal to the threshold value TH12 (YES in S411), a positive additional value A12 (e.g., “1”) that is smaller than the preset additional value A11 is added to the judgment value V1 (S413), and the process is returned.

If it is decided not to be smaller than or equal to the threshold value TH12 (NO in S411), it is decided whether or not a difference obtained by subtracting the parameter EM from the parameter E1 is smaller than or equal to the preset positive threshold value TH21 as shown in FIG. 10 (S415). If it is decided to be smaller than or equal to the threshold value TH21 (YES in S415), the preset positive additional value A21 (e.g., “2”) is added to the judgment value V2 (S417), and the process is returned.

If it is decided not to be smaller than or equal to the threshold value TH21 (NO in S415), it is decided whether a difference obtained by subtracting the parameter EM from the parameter E1 is smaller than or equal to a positive threshold value TH22 that is larger than the preset threshold value TH21 (S419). If it is decided to be smaller than or equal to the threshold value TH22 (YES in S419), a positive additional value A22 (e.g., “1”) that is smaller than the preset additional value A21 is added to the judgment value V2 (S421), and the process is returned.

If it is decided not to be smaller than or equal to the threshold value TH22 (NO in S421), it is decided whether or not a difference obtained by subtracting the parameter EM from the parameter E1 is larger than or equal to a preset positive threshold value TH31 (S423). If it is decided to be larger than or equal to the threshold value TH31 (YES in S423), a preset positive additional value A31 (e.g., “2”) is added to the judgment value V3 (S425), and the process is returned.

If it is decided not to be larger than or equal to the threshold value TH31 (NO in S423), it is decided whether or not a difference obtained by subtracting the parameter EM from the parameter EI is smaller than or equal to a positive threshold value TH32 that is smaller than the preset threshold value TH31 (S427). If it is decided to be smaller than or equal to the threshold value TH32 (YES in S427), a positive additional value A32 (e.g., “1”) that is smaller than the preset additional value A31 is added to the judgment value V3 (S429), and the process is returned.

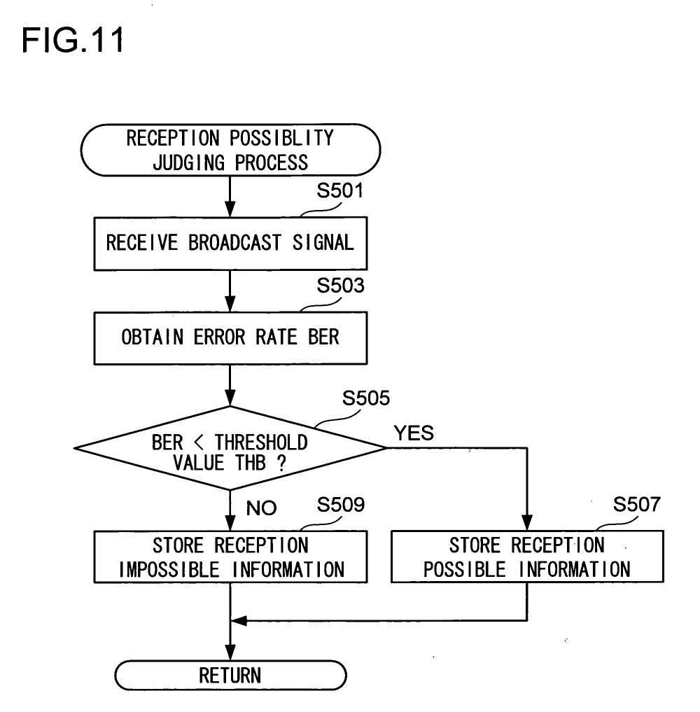

FIG. 11 is a detail flowchart to show an example of the reception possibility judging process performed in the step S115 of the flowchart shown in FIG. 5. First, the second intensity obtaining unit 116 receives a broadcast signal via the receiving unit 15 (S501). Then, the second intensity obtaining unit 116 obtains the bit error rate BER (S503). Next, the direction setting unit 117 decides whether or not the bit error rate BER obtained in step S503 is smaller than the preset predetermined threshold value THB (S505).

If it is decided to be smaller than the threshold value THB (YES in S505), the direction setting unit 117 decides that reception can be performed. Then, information indicating that reception can be performed is stored in the setting direction storage unit 123 (S507), and the process is returned. If it is decided to be larger than or equal to the threshold value THB (NO in S505), the direction setting unit 117 decides that reception cannot be performed. Then, information indicating that reception cannot be performed is stored in the setting direction storage unit 123 (S509), and the process is returned.

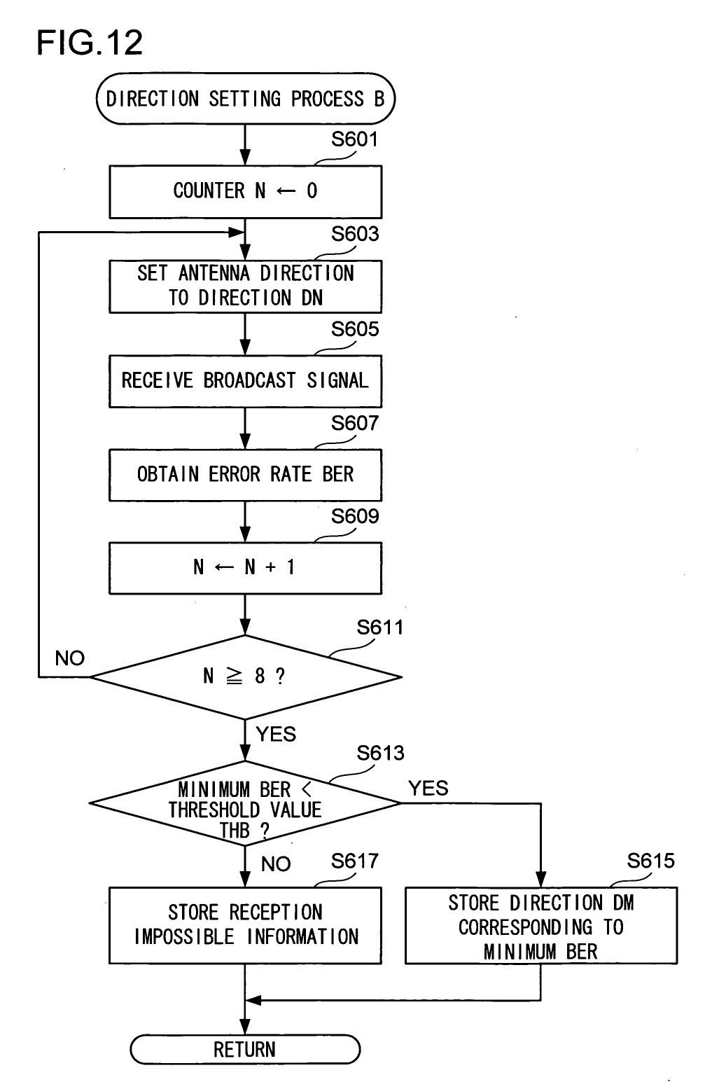

FIG. 12 is a detail flowchart to show an example of the direction setting process B performed in step S119 of the flowchart shown in FIG. 5. First, the second intensity obtaining unit 116 sets the counter N for counting directions of the antenna to the initial value “0” (S601). Then, the second intensity obtaining unit 116 sets the direction of the antenna connected to the antenna unit 151 to a direction DN (here, N is a value of the counter N that is one of numbers 0-7) (S603). Next, the second intensity obtaining unit 116 receives a broadcast signal via the receiving unit 15 (S605). Next, the second intensity obtaining unit 116 obtains the bit error rate BER (S607). Then, the second intensity obtaining unit 116 increments a value of the counter N by one (S609), and it is decided whether or not a value of the counter N is larger than or equal to eight (S611). If it is decided not to be larger than or equal to eight (i.e., smaller than or equal to seven) (NO in S611), the process goes back to the step S603, and the process in the step S603 and the subsequent steps is performed repeatedly.

If it is decided to be larger than or equal to eight (YES in S611), the direction setting unit 117 decides whether or not the minimum bit error rate BER among eight bit error rates BER obtained in the step S607 is smaller than the preset predetermined threshold value THB (S613). If it is decided to be smaller than or equal to the threshold value THB (YES in S613), the direction setting unit 117 stores information indicating that reception can be performed and the direction DM corresponding to the minimum bit error rate BER (a value of M that is one of values 0-7) in the setting direction storage unit 123 (S615), and the process is returned. If it is decided to be larger than or equal to the threshold value THB (NO in S613), the direction setting unit 117 decides that reception cannot be performed. Then, information indicating that reception cannot be performed is stored in the setting direction storage unit 123 (S617), and the process is returned.

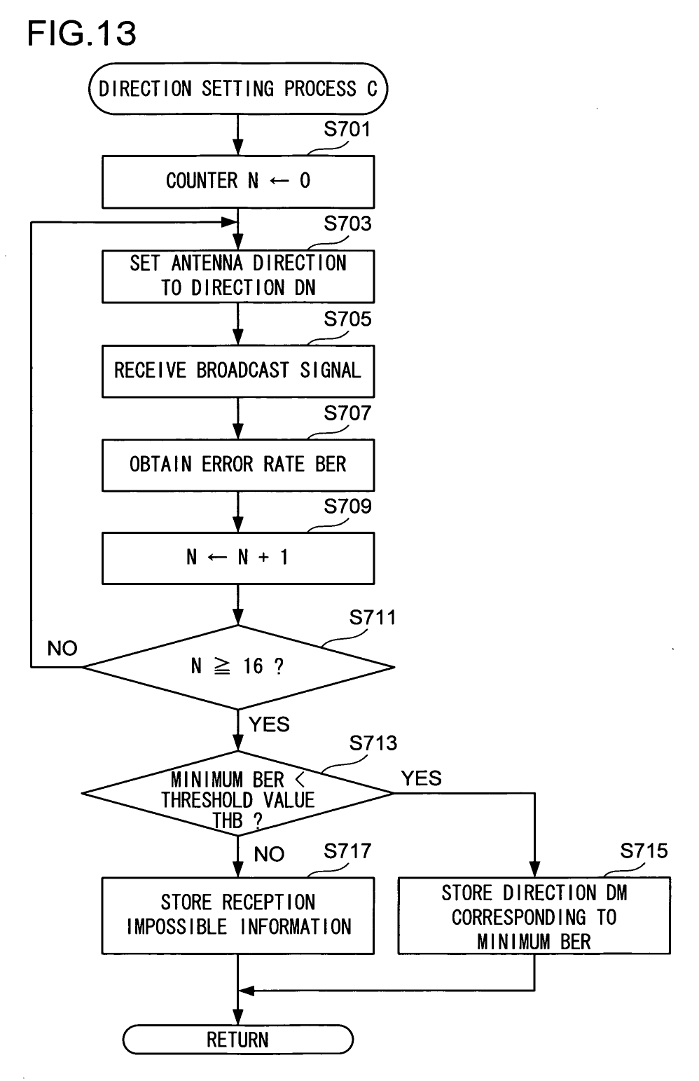

FIG. 13 is a detail flowchart to show an example of the direction setting process C that is performed in the step S121 of the flowchart shown in FIG. 5. First, the second intensity obtaining unit 116 sets the counter N for counting directions of the antenna to the initial value “0” (S701). Then, the second intensity obtaining unit 116 sets the direction of the antenna connected to the antenna unit 151 to the direction DN (here, N is a value of the counter N that is one of numbers 0-15) (S703). Next, the second intensity obtaining unit 116 receives a broadcast signal via the receiving unit 15 (S705). Next, the second intensity obtaining unit 116 obtains the bit error rate BER (S707). Then, the second intensity obtaining unit 116 increments a value of the counter N by one (S709), and it is decided whether or not a value of the counter N is larger than or equal to sixteen (S711). If it is decided not to be larger than or equal to sixteen (i.e., to be smaller than or equal to 15) (NO in S711), the process goes back to the step S703, and the process in step S703 and the subsequent steps is performed repeatedly.

If it is decided to be larger than or equal to sixteen (YES in S711), the direction setting unit 117 decides whether or not the minimum bit error rate BER among sixteen bit error rates BER obtained in the step S707 is smaller than the preset predetermined threshold value THB (S713). If it is decided to be smaller than or equal to the threshold value THB (YES in S713), the direction setting unit 117 stores information indicating that reception can be performed and the direction DM corresponding to minimum bit error rate BER (a value of M that is one of values 0-15) in the setting direction storage unit 123 (S715), and the process is returned. If it is decided to be larger than or equal to the threshold value THB (NO in S713), the direction setting unit 117 decides that reception cannot be performed. Then, information indicating that reception cannot be performed is stored in the setting direction storage unit 123 (S717), and the process is returned.

In this way, it is decided whether or not the antenna connected to the antenna unit 151 is a smart antenna. If it is decided that the antenna is a smart antenna, it is decided whether the connected antenna is a bidirectional antenna having directivities in two directions forming substantially 180 degrees with each other or a unidirectional antenna having directivity only in one direction. Only in the case where it is decided that the antenna is a smart antenna, the connected antenna is set in a plurality of prescribed directions so that reception intensities are obtained for the individual setting directions. In addition, if it is decided that the antenna is a bidirectional antenna, the connected antenna is set in a plurality of prescribed directions between a prescribed direction and the direction forming 180 degrees with each other (here, eight directions D0-D7) so that reception intensities are obtained for the individual setting directions (see FIG. 12). If it is decided that the antenna is a unidirectional antenna, the connected antenna is set in a plurality of prescribed directions between a prescribed direction and the direction forming 360 degrees with each other (here, sixteen directions D0-D15) so that reception intensities are obtained for the individual setting directions (see FIG. 13). Further, since the direction of the connected antenna is set to a direction of the maximum reception intensity among the obtained reception intensities, the optimal reception direction can be set efficiently.

More specifically, since reception intensities in appropriate number of directions are obtained in accordance with a type of the antenna (i.e., whether the antenna is a smart antenna or not and whether the antenna is a bidirectional antenna or not), the optimal reception direction can be set efficiently. In other words, if it is decided that the antenna is not a smart antenna, it is not necessary to obtain reception intensities in a plurality of directions, so the optimal reception direction can be set efficiently (see FIG. 11). Further, if it is decided that the antenna is a bidirectional antenna, the connected antenna is set in a plurality of prescribed directions between a prescribed direction and the direction forming 180 degrees with each other (here, eight directions D0-D7, see FIG. 4A) so that reception intensities are obtained for the individual setting directions (see FIG. 12). Then, the direction of the connected antenna is set in a direction of the maximum reception intensity among the obtained reception intensities. Therefore, compared with the case where the antenna is a unidirectional antenna (see FIG. 13), the time necessary for obtaining reception intensities can be reduced approximately by half.

In addition, if it is decided that the antenna is a bidirectional antenna, the connected antenna is set to eight directions forming 22.5 degrees between neighboring directions between a prescribed direction and the direction forming 180 degrees with each other (i.e., eight directions D0-D7, see FIG. 4A) (see FIG. 12). If it is decided that the antenna is a unidirectional antenna, the connected antenna is set to sixteen directions forming 22.5 degrees between neighboring directions between a prescribed direction and the direction forming 360 degrees with each other (i.e., sixteen directions D0-D15, see FIG. 4A) (see FIG. 13). Therefore, the optimal reception direction can be set more efficiently.

More specifically, since the connected antenna is set to eight directions (or sixteen directions) forming a constant angle (here, 22.5 degrees) between neighboring directions, reception intensities in directions corresponding to a spreading angle of directivity of the antenna can be obtained (see FIG. 4). Therefore, the optimal reception direction can be set more efficiently.

In addition, the antenna connected to the antenna unit 151 is set to a plurality of preset (here, sixteen, see FIG. 4A) directions so that reception intensities in the individual setting directions are obtained. Then, it is decided whether or not the antenna connected to the antenna unit 151 is a smart antenna based on the reception intensities in the individual obtained directions. If it is decided that the connected antenna is a smart antenna, it is decided whether the connected antenna is a bidirectional antenna having directivities in two directions forming substantially 180 degrees with each other (see FIG. 4B) or a unidirectional antenna having its directivity only in one direction (see FIG. 4C) based on the reception intensities in the individual obtained directions. Therefore, a type of the connected antenna (i.e., whether the antenna is a smart antenna or not and whether the antenna is a bidirectional antenna or not) can be decided.

More specifically, since it is decided whether the antenna is a bidirectional antenna having directivities in two directions forming substantially 180 degrees with each other or a unidirectional antenna having its directivity only in one direction, the optimal reception direction can be determined efficiently. If it is decided that the antenna is a bidirectional antenna, the optimal reception direction can be determined among the eight directions D0-D7 for the reception intensities shown in FIG. 4A (see FIG. 12).

In addition, among a plurality of preset channels (here, 68 channels of the channel numbers “2” to “69”), channels that are received via the connected antenna are set one by one, so that reception intensities of the individual channels are obtained. Then, it is decided whether or not the set channel is a channel belonging to the UHF band or a channel belonging to the VHF band. Then, it is decided whether or not the connected antenna is a smart antenna and whether or not the connected antenna is a bidirectional antenna discriminating the channels decided to belong to the UHF band from the channel belonging to the VHF band. Therefore, a type of the connected antenna (i.e., whether the antenna is a smart antenna or not and whether the antenna is a bidirectional antenna or not) can be decided more correctly.

More specifically, at least one of whether or not the connected antenna is a smart antenna and whether or not the connected antenna is a bidirectional antenna is decided discriminating the channels decided to belong to the UHF band from the channel belonging to the VHF band. Since there may be the case where the decision result for the channel decided to belong to the UHF band is different from that for the channel belonging to the VHF band, a type of the connected antenna (i.e., at least one of whether or not the antenna is a smart antenna and whether or not the antenna is a bidirectional antenna) can be decided more correctly.

In addition, the connected antenna is set to four directions forming 90 degrees between neighboring directions (here, directions D0, D4, D8 and D12 shown in FIG. 4A), so that reception intensities in the individual setting directions are obtained. Then, it is decided whether or not the connected antenna is a smart antenna and whether or not the antenna is a bidirectional antenna based on the maximum reception intensity (here, the parameter EM) among the reception intensities in the individual obtained directions, the reception intensity (here, the parameter ER) in the direction (e.g., the direction D4) forming 90 degrees with the direction in which the maximum reception intensity is obtained (e.g., the direction D0) and the reception intensity (here, the parameter EI) in the direction (e.g., the direction D8) forming 180 degrees with the direction in which the maximum reception intensity is obtained (see FIGS. 9 and 10). Therefore, a type of the connected antenna (i.e., at least one of whether or not the antenna is a smart antenna and whether or not the antenna is a bidirectional antenna) can be decided simply and correctly.

More specifically, since it is decided whether or not the connected antenna is a smart antenna and whether or not the antenna is a bidirectional antenna based on the maximum reception intensity (here, the parameter EM), the reception intensity (here, the parameter ER) in the direction forming 90 degrees with the direction in which the maximum reception intensity is obtained and the reception intensity (here, the parameter EI) in the direction forming 180 degrees with the direction in which the maximum reception intensity is obtained, it is decided that the antenna is not a smart antenna if the maximum reception intensity (here, the parameter EM) is approximately the same as the reception intensity (here, the parameter ER) in the direction forming 90 degrees with the direction in which the maximum reception intensity is obtained, for example. In addition, it is decided that the antenna is a bidirectional antenna if the maximum reception intensity (here, the parameter EM) is approximately the same as the reception intensity (here, the parameter EI) in the direction forming 180 degrees with the direction in which the maximum reception intensity is obtained, for example. Therefore, a type of the connected antenna (i.e., whether the antenna is a smart antenna or not and whether the antenna is a bidirectional antenna or not) can be decided simply and correctly.

Further, since the judgment values V1-V3 and U1-U3 are updated in accordance with reception states (values of the parameters EM, ER and EI) of the individual channels as shown in FIGS. 9 and 10 while it is decided whether or not the connected antenna is a smart antenna and whether or not the antenna is a bidirectional antenna based on the judgment values V1-V3 and U1-U3 as shown in FIGS. 6 and 7, a type of the connected antenna (i.e., whether the antenna is a smart antenna or not and whether the antenna is a bidirectional antenna or not) can be decided simply and correctly.

Note that the present invention can also be applied to the following structures.

(A) Although the broadcasting receiving apparatus is the digital broadcasting receiver 1 in the embodiment described above, it may be a broadcasting receiver that receives an analog broadcast signal or a broadcasting receiver that receives an analog broadcast signal and a digital broadcast signal. If the broadcasting receiving apparatus receives and analog broadcast signal, an S/N ratio may be used as the reception intensity instead of the bit error rate BER for evaluation.

(B) Although the monitor is the display 183 that is provided to the digital broadcasting receiver 1 in the embodiment described above, the monitor may be structured as a device that is separate from the digital broadcasting receiver 1. For example, the monitor can be made up of an LCD (Liquid Crystal Display) or the like that is provided to a personal computer or the like.

(C) Although the MPU 11 works as the functional units including the channel setting unit 111, the channel judging unit 112, the first intensity obtaining unit 113, the judgment value determining unit 114, the antenna judging unit 115, the second intensity obtaining unit 116, the direction setting unit 117 and the like in the embodiment described above, at least one of the channel setting unit 111, the channel judging unit 112, the first intensity obtaining unit 113, the judgment value determining unit 114, the antenna judging unit 115, the second intensity obtaining unit 116 and the direction setting unit 117 may be structured by hardware such as a circuit.

(D) Although the second intensity obtaining unit 116 sets the connected antenna to eight directions (the directions D0-D7) if it is decided that the antenna is a bidirectional antenna in the embodiment described above, it is sufficient that the second intensity obtaining unit 116 sets the antenna in a plurality of prescribed directions between a prescribed direction and the direction forming 180 degrees with each other. For example, it is possible to adopt another structure in which the second intensity obtaining unit 116 sets the antenna in 18 directions forming 10 degrees between neighboring directions.

Further, although the second intensity obtaining unit 116 sets the connected antenna to sixteen directions (the directions D0-D15) if it is decided that the antenna is a unidirectional antenna in the same manner, it is sufficient that the second intensity obtaining unit 116 sets the antenna in a plurality of prescribed directions between a prescribed direction and the direction forming 360 degrees with each other. For example, it is possible to adopt another structure in which the second intensity obtaining unit 116 sets the antenna in 36 directions forming 10 degrees between neighboring directions.

What is claimed is:

1. A broadcasting receiving apparatus to which a smart antenna as an antenna having a changeable directivity direction is connectable and which can receive television broadcast through the connected antenna and output the received television broadcast onto a monitor, the apparatus comprising:
a first judging unit for deciding whether or not the connected antenna is a smart antenna;
a second judging unit for deciding whether the connected antenna is a bidirectional antenna having directivities in two directions forming substantially 180 degrees with each other or a unidirectional antenna having its directivity only in one direction if it is decided that the connected antenna is a smart antenna by the first judging unit;
an intensity obtaining unit for setting the connected antenna in a plurality of prescribed directions and for obtaining reception intensities in the individual setting directions only in the case where the first judging unit decides that the connected antenna is a smart antenna; and
a direction setting unit for setting a direction of the connected antenna in a direction of a maximum reception intensity among the reception intensities obtained by the intensity obtaining unit, wherein
the intensity obtaining unit sets the connected antenna in a plurality of prescribed directions between a prescribed direction and the direction forming 180 degrees with each other so as to obtain reception intensities in the individual setting directions if the second judging unit decides that the connected antenna is a bidirectional antenna,
while the intensity obtaining unit sets the connected antenna in a plurality of prescribed directions between a prescribed direction and the direction forming 360 degrees with each other so as to obtain reception intensities in the individual setting directions if the second judging unit decides that the connected antenna is a unidirectional antenna.

2. The broadcasting receiving apparatus according to claim 1, wherein
the intensity obtaining unit sets the connected antenna in eight directions forming 22.5 degrees between neighboring directions between a prescribed direction and the direction forming 180 degrees with each other if the second judging unit decides that the connected antenna is a bidirectional antenna,
while the intensity obtaining unit sets the connected antenna in sixteen directions forming 22.5 degrees between neighboring directions between a prescribed direction and the direction forming 360 degrees with each other if the second judging unit decides that the connected antenna is a unidirectional antenna.

3. A broadcasting receiving apparatus to which a smart antenna as an antenna having a changeable directivity direction is connectable and which can receive television broadcast through the connected antenna and output the received television broadcast onto a monitor, the apparatus comprising:
a first judging unit for deciding whether or not the connected antenna is a smart antenna;
a second judging unit for deciding whether the connected antenna is a bidirectional antenna having directivities in two directions forming substantially 180 degrees with each other or a unidirectional antenna having its directivity only in one direction if it is decided that the connected antenna is a smart antenna by the first judging unit;
an intensity obtaining unit for setting the connected antenna in a plurality of prescribed directions and for obtaining reception intensities in the individual setting directions only in the case where the first judging unit decides that the connected antenna is a smart antenna; and
a direction setting unit for setting a direction of the connected antenna to a direction of a maximum reception intensity among the reception intensities obtained by the intensity obtaining unit, wherein
the intensity obtaining unit sets the connected antenna in eight directions forming 22.5 degrees between neighboring directions between a prescribed direction and the direction forming 180 degrees with each other so as to obtain reception intensities in the individual setting directions if the second judging unit decides that the connected antenna is a bidirectional antenna,
while the intensity obtaining unit sets the connected antenna in sixteen directions forming 22.5 degrees between neighboring directions between a prescribed direction and the direction forming 360 degrees with each other so as to obtain reception intensities in the individual setting directions if the second judging unit decides that the connected antenna is a unidirectional antenna.
